(19) United States
(12) Patent Application Publication
(10) Pub. No.: US 2002/0079582 A1
(43) Pub. Date: Jun. 27, 2002

(54) Semiconductor device and method for its manufacture

(76) Inventor: Yoshihiro Satoh, Tokyo (JP)

Correspondence Address: Darryl G. Walker, WALKER & SAKO, LLP, Suite 235, 300 South First Street, San Jose, CA, 95113, US

(21) Appl. No.: 09/981,402

(22) Filed: Oct. 17, 2001

(30) Foreign Application Priority Data
Oct. 20, 2000 (JP) 2000-320402

(51) Int. Cl. H01L 21/8234; H01L 21/8244; H01L 21/8242

(52) U.S. Cl. 257/751; 438/253; 438/396; 438/786

(57) ABSTRACT

A semiconductor device is disclosed including a transistor that may have desired characteristics due to a silicon nitride film that may prevent carbon from diffusing to a silicon substrate. The semiconductor device (60) may include a device structure having an insulating film formed from gas containing carbon. A silicon nitride film may be formed between the insulating film and a transistor formation region in the silicon substrate for preventing carbon from diffusing to the silicon substrate.

### TECHNICAL FIELD

The present invention relates generally to a semiconductor device and method for its manufacture, and more specifically to a semiconductor device including a transistor structure having an insulating film which is formed from gas containing carbon and a method for manufacturing such a semiconductor device.

### BACKGROUND OF THE INVENTION

A dynamic random access memory (DRAM) generally has memory cells that consist of one transistor and one capacitor. The transistor is typically a metal oxide semiconductor field effect transistor (IGFET). The capacitor includes three layers that are a lower electrode, an upper electrode and a high dielectric insulating film disposed between the electrodes.

Because the geometries on a DRAM are continuously becoming finer, the surface area of the semiconductor substrate that is consumed by each memory cell capacitor needs to be reduced.

In order to keep a satisfactory capacitance value as the size of the memory cell capacitor is reduced, a high dielectric film can be used as the insulating film between the capacitor electrodes. The high dielectric film has a larger dielectric constant than that of silicon nitride. An example of a high dielectric film is tantalum oxide (Ta₂O₅).

The structure of a conventional DRAM sill now be described with reference to FIGS. 16 and 17.

FIG. 16(a) is a cross-sectional diagram illustrating a word line layer on a conventional DRAM 10 after various processing steps. The cross-section diagram of FIG. 16(a) is perpendicular to the word line in a memory cell region. FIG. 16(b) is a cross-sectional diagram illustrating contact plugs and isolation regions in the conventional DRAM 10 after various processing steps. The cross-sectional diagram of FIG. 16(b) is parallel to the word line in a memory cell region.

A transistor formation region in a silicon substrate 12 is defined by a shallow trench isolation (STI) 14 which serves as a device isolation region. A diffusion layer containing source/drain regions (not shown) and a channel region is formed in the transistor formation region.

A word line 22 of conventional DRAM 10 is formed on the transistor formation region. The word line 22 consists of a laminate film consisting of a phosphorus-doped polysilicon film (DOPOS) 16, tungsten silicide (WSi) film 18, a silicon nitride film 20, and a silicon nitride film side wall 24. The word line 22 provides a gate electrode for a transistor formed in the transistor formation region.

A first interlayer insulating film 26 is formed on word line 22. A cell contact hole is formed between word lines 22 to expose the silicon substrate 12 through first interlayer insulating film 26. Cell contact hole is filled with an electrically conductive material such as DOPOS and tungsten (W) to form a cell contract plug 30.

FIG. 17 is a cross-sectional diagram illustrating the construction of a bit line 38 and cylindrical capacitor section 50 of conventional DRAM 10 will be described. The cross-sectional diagram of FIG. 17 is parallel to the word line in a memory cell region.

A second interlayer insulating film 32 is formed on first interlayer insulating layer 26. Bit line 38 is formed on second interlayer insulating film 32 and buried in third interlayer insulating film 42. Bit line 38 is composed of a wiring of laminate film of tungsten nitride film 33, tungsten (W) film 34, a silicon nitride film 36, and a silicon nitride film side wall 40.

A contact hole 44 is formed between bit lines 38 and filled with an electrically conductive material such as DOPOS and tungsten (W) to form a capacitor contact plug 46.

A fourth interlayer insulating film 48 is formed on third interlayer insulating film 42 and capacitor contact plug 46. A deeply recessed cylindrical capacitor formation section 50 is formed in fourth interlayer insulating film 48 to expose capacitor contact plug 46.

A lower electrode, a capacitor insulating film of Ta₂O₅, and an upper electrode are formed in the cylindrical capacitor formation section 50, although not illustrated.

A conventional method for manufacturing a conventional DRAM will now be described with reference to FIGS. 18 to 21. FIGS. 18(a)-(c), 19(d)-(e), 20(f)-(h), and 21(i)-(k) are cross-sectional views of the conventional DRAM after various processing steps.

FIGS. 18(a)-(c) are cross sectional views that are taken perpendicular to the word lines

Referring now to FIG. 18(a), STI 14 is formed in silicon substrate 12 as the device isolation region to define the transistor formation region. On the transistor formation region, a diffusion layer that includes a channel region and source/drain regions (not shown) is formed. Thereafter a wiring is formed with a laminate film composed of DOPOS film 16, WSi film 18, and silicon nitride film 20 on a gate oxide film 15.

Next, a silicon nitride film is formed on the laminate film including the gate oxide film 15 and etched back to form silicon nitride film sidewall 24 as illustrated in FIG. 18(b). Word line 22 is thus formed which includes the sidewall on the laminate. Word line 22 provides a gate electrode for a transistor formed in the transistor formation region.

Then, as illustrated in FIG. 18(c), first layer insulating film 26 is formed on the entire surface of the substrate to bury the word line 22. First layer insulating film 26 is then etched by a selective etching method for silicon nitride films (20 and 24) to open cell contact hole 28 and expose silicon substrate 12.

FIG. 19(d) is a cross-sectional view that is taken perpendicular to the word lines. FIG. 19(e) is a cross-sectional view that is taken parallel to the word lines and perpendicular to the bit lines.

As illustrated in FIG. 19(d) and FIG. 19(e), cell contact hole 28 is filled by deposition of an electrically conductive material such as DOPOS, tungsten (W), or the like on the entire surface of the substrate. The electrically conductive material on the first interlayer insulating film 26 is removed by an entire etching back method such as chemical mechanical polish (CMP) to form cell contact plug 30 which is connected with the diffusion layer of silicon substrate 12.

FIGS. 20(f)-(h) are cross-sectional views that are taken parallel to the word lines and perpendicular to the bit lines.

As illustrated in FIG. 20(f), a second interlayer insulating film 32 is formed on first interlayer insulating film 26 and cell contact plug 30. A wiring formed by a laminate film that consists of a tungsten nitride film 33, a tungsten film 34, and silicon nitride film 36 formed on second interlayer insulating film 32.

Then, silicon nitride film 40 is formed on the wiring of the laminate film and then etched back to form a silicon nitride film sidewall 40, so that bit line 38 is formed as illustrated in FIG. 20(g).

As illustrated in FIG. 20(h), a third interlayer insulating film 42 is then formed on the entire surface of the substrate to bury bit line 38.

FIGS. 21(i)-(k) are cross-sectional views that are taken parallel to the word lines and perpendicular to the bit lines.

As illustrated in FIG. 21(i), a contact hole 44 for forming a capacitor contact is formed to expose cell contact plug 30. Contact hole 44 is formed by etching third interlayer insulating film 42 and second interlayer insulating film 32 with a selective etching method for silicon nitride films (36 and 40).

As illustrated in FIG. 21(j), an electrically conductive material film such as DOPOS, tungsten, etc., is formed to fill contact hole 44. The electrically conductive material on third interlayer insulating film 42 is removed by an entire etching back method or a CMP method so that capacitor contact plug 46 is formed on the substrate. Contact plug 46 comprises an electrically conductive material and is connected with cell contact plug 30.

Then, as illustrated in FIG. 21(k), a fourth interlayer insulating film 48 for formation of the cylindrical capacitor is formed on third interlayer insulating film 42 and capacitor contact plug 46. Fourth interlayer insulating film 48 is patterned to open a cylindrical capacitor formation section 50 and expose capacitor contact plug 46.

A lower electrode, a Ta₂O₅ film, and an upper electrode are then formed to provide the cylindrical capacitor. The formation of the Ta₂O₅ film is achieved by a chemical vapor deposition (CVD) method employing pentaethoxy-tantalum Ta(OC₂H₅)₅ as stock gas. At the time of the formation, the Ta₂O₅ film is not sufficiently oxidized, so it is subject to oxidization (crystallization) to assure the insulation properties.

The aforementioned conventional method for manufacturing a DRAM suffers from the deficiency that transistor characteristics of the DRAM may be varied.

Referring now to FIG. 15, a graph illustrating the current-voltage characteristics of a transistor such as a MOSFET formed on the conventional DRAM 10 with the conventional method as described is set forth.

In FIG. 15, the current-voltage characteristics of the transistor formed with the conventional method is illustrated with the broken line. Also, an ideal designed current-voltage characteristic is illustrated with a thicker dashed line. It is noted that the current-voltage characteristics of the transistor formed with the conventional method diverge from the ideal designed value when the gate voltage is below approximately 0.8 volts. Thus, the threshold voltage of the transistor formed with the conventional method differs greatly from the ideal designed value.

Although in the aforementioned description, the variations of the transistor characteristics of a semiconductor device were illustrated in a DRAM, the deficiencies with the conventional method may correspond to any semiconductor device that includes a transistor structure formed on a silicon substrate and containing an insulating film formed from gas containing carbon.

In light of the above discussion, it would be desirable to provide a semiconductor device which includes a transistor structure formed on a silicon substrate and including an insulating film formed from a gas containing carbon while having desirable transistor characteristics. It would also be desirable to provide a method of manufacturing such a semiconductor device.

### SUMMARY OF THE INVENTION

A semiconductor device according to the present embodiments may include a transistor that may have desired characteristics due to a silicon nitride film that may prevent carbon from diffusing to a silicon substrate. The semiconductor device may include a device structure having an insulating film formed from gas containing carbon. A silicon nitride film may be formed between the insulating film and a transistor formation region in the silicon substrate. In this way, carbon may be prevented from diffusing to the silicon substrate.

According to one aspect of the embodiments, a semiconductor device on a silicon substrate may include a device structure having an insulating film formed from gas containing carbon. A silicon nitride film may be formed between the insulating film and the silicon substrate for preventing carbon from diffusing to the silicon substrate.

According to another aspect of the embodiments, the insulating film may include tantalum oxide.

According to another aspect of the embodiments, the semiconductor device may be a dynamic random access memory (DRAM). The DRAM may include a memory cell having a memory cell capacitor. The tantalum oxide film may be a capacitor insulting film of the memory cell capacitor.

According to another aspect of the embodiments, the semiconductor device may include a contact which may penetrate an interlayer insulating film and may be electrically connected with a diffusion layer in the silicon substrate. The silicon nitride film may be formed on the silicon substrate as a carbon diffusion preventing film while traversing a region except a portion for providing the electrical connection between the contact and the diffusion layer.

According to another aspect of the embodiments, the semiconductor device may include a contact that may penetrate a first interlayer insulating film and may be electrically connected with a diffusion layer formed in the silicon substrate. A capacitor contact may be interposed between a lower electrode of the memory cell capacitor and the contact while penetrating a second interlayer insulating film and a third interlayer insulating film. The silicon nitride film may be formed on the third interlayer insulating film while traversing a region except a connection portion between the lower electrode and the capacitor contact.

According to another aspect of the embodiments, the semiconductor device may include a contact that can be electrically connected with the diffusion layer formed in the silicon substrate while penetrating the interlayer insulating film. The contact may be electrically connected to a capacitor contact that may be interposed between a lower electrode of the memory cell capacitor and the contact. The capacitor contact may penetrate a second interlayer insulating film and a third interlayer insulating film and may provide an electrical connection between the lower electrode and the contact. The silicon nitride film may be formed between the second and third insulation films.

According to another aspect of the embodiments, a method for manufacturing a semiconductor device on a silicon substrate wherein the semiconductor device may include a device structure having an insulating film formed from gas containing carbon may include the step of forming a silicon nitride film between the insulating film and the silicon substrate. The silicon nitride film may prevent carbon from diffusing to the silicon substrate.

According to another aspect of the embodiments, the method for manufacturing the semiconductor device may include the steps of forming a word line on a silicon substrate, forming the silicon nitride over the entire surface of the substrate including the word line, forming a first interlayer insulating film on the silicon nitride film, etching the first interlayer insulating film to form a cell contact hole with an etching method that may be selective for the silicon nitride film to expose the silicon nitride film at a bottom of the cell contact hole, selectively etching the silicon nitride film exposed at the bottom of the cell contact hole to expose the silicon substrate, and forming a cell contact plug in the cell contact hole.

According to another aspect of the embodiments, the method for manufacturing the semiconductor device may include the steps of forming a first capacitor electrode that may be electrically connected to the cell contact plug, forming the insulating film, and forming a second capacitor electrode on the insulating film.

According to another aspect of the embodiments, the method for manufacturing the semiconductor device may include tantalum oxide in the insulating film.

According to another aspect of the embodiments, the method for manufacturing the semiconductor device may include the steps of forming a word line on a silicon substrate, forming a first interlayer insulating film on the silicon substrate including the word line, forming a cell contact plug through the first interlayer insulating film to provide an electrical connection with a diffusion layer in the silicon substrate, forming a second interlayer insulating film on the first interlayer insulating film, forming a bit line on the second interlayer insulating film, forming a third interlayer insulating film on the second interlayer insulating film including the bit line, forming a capacitor contact plug through the second and third interlayer insulating films to provide an electrical connection to the cell contact plug, and forming the silicon nitride film on the third interlayer insulating film.

According to another aspect of the embodiments, the method for manufacturing the semiconductor device may include the steps of forming a fourth interlayer insulating film on the silicon nitride film, forming a capacitor formation section in the fourth interlayer insulating film to expose the silicon nitride film, and etching the exposed silicon nitride film to expose the capacitor contact plug.

According to another aspect of the embodiments, the method for manufacturing the semiconductor device may include the step of forming a capacitor including the insulating film in the capacitor formation section.

According to another aspect of the embodiments, the method for manufacturing the semiconductor device may include the steps of forming a word line on a silicon substrate, forming a first interlayer insulating film on the silicon substrate including the word line, forming a cell contact plug through the first interlayer insulating film to provide an electrical connection with a diffusion layer in the silicon substrate, forming a second interlayer insulating film on the first interlayer insulating film, forming a bit line on the second interlayer insulating film, forming a third interlayer insulating film on the second interlayer insulating film including the bit line, forming the silicon nitride film on the third interlayer insulating film, and forming a capacitor contact plug through the second and third interlayer insulating films and the silicon nitride film to provide an electrical connection to the cell contact plug.

According to another aspect of the embodiments, the method for manufacturing the semiconductor device may include the steps of forming a capacitor including the insulating film and having a capacitor electrode electrically connected to the capacitor contact plug.

According to another aspect of the embodiments, the method for manufacturing the semiconductor device may include the steps of forming a word line on a silicon substrate, forming a first interlayer insulating film on the silicon substrate including the word line, forming a cell contact plug through the first interlayer insulating film to provide an electrical connection with a diffusion layer in the silicon substrate, forming a second interlayer insulating film on the first interlayer insulating film, forming a bit line on the second interlayer insulating film, forming the silicon nitride film on the second interlayer insulating film including the bit line, forming a third interlayer insulating film on the silicon nitride film, etching the third interlayer insulating film to form a contact hole and expose the silicon nitride film at a bottom of the contact hole, etching the silicon nitride film at the bottom of the contact hole to expose the second interlayer insulating film, etching the exposed second interlayer insulating film at the bottom of the contact hole to provide a capacitor contact hole including the contact hole, and forming a capacitor contact plug through the second and third interlayer insulating films to provide an electrical connection to the cell contact plug.

According to another aspect of the embodiments, the method for manufacturing the semiconductor device may include the step of forming a capacitor including the insulating film and having a capacitor electrode electrically connected to the capacitor contact plug.

According to another aspect of the embodiments, a method for manufacturing a semiconductor device on a silicon substrate wherein the semiconductor device may include a memory cell having a capacitor insulating film formed from gas containing carbon may include the step of forming a silicon nitride film between the capacitor insulating film and the silicon substrate. The silicon nitride film may prevent carbon from diffusing to the silicon substrate.

According to another aspect of the embodiments, the method for manufacturing the semiconductor device may include tantalum oxide in the capacitor insulating film.

According to another aspect of the embodiments, the capacitor may include an electrode having a hemispherical grain structure.

### BRIEF DESCRIPTION OF THE DRAWINGS

FIG. 1 is a cross-sectional view of a portion of a DRAM after various processing steps according to an embodiment.

FIGS. 2(a)-(c) are cross-sectional views illustrating a DRAM after various processing steps according to an embodiment.

FIGS. 3(d)-(f) are cross-sectional views illustrating a DRAM after various processing steps according to an embodiment.

FIGS. 5(a)-(c) are cross-sectional views illustrating a DRAM after various processing steps according to an embodiment.

FIGS. 6(d)-(f) are cross-sectional views illustrating a DRAM after various processing steps according to an embodiment.

FIGS. 7(g)-(i) are cross-sectional views illustrating a DRAM after various processing steps according to an embodiment.

FIGS. 8(j)-(l) are cross-sectional views illustrating a DRAM after various processing steps according to an embodiment.

FIGS. 9(a)-(c) are cross-sectional views illustrating a DRAM after various processing steps according to an embodiment.

FIG. 10 is a cross-sectional view illustrating a DRAM after various processing steps according to an embodiment.

FIG. 11 is a cross-sectional view of a portion of a DRAM after various processing steps according to an embodiment.

FIGS. 12(a)-(c) are cross-sectional views illustrating a DRAM after various processing steps according to an embodiment.

FIGS. 13(d)-(f) are cross-sectional views illustrating a DRAM after various processing steps according to an embodiment.

FIG. 14 is a top plan view of the structure of a DRAM according to an embodiment.

FIG. 15 is a graph illustrating the current-voltage characteristics of transistors such as a MOSFET formed on a DRAM according to an embodiment and a conventional method.

FIGS. 16(a)-(b) are cross-sectional views illustrating a conventional DRAM after various processing steps.

FIG. 17 is a cross-sectional view illustrating a conventional DRAM after various processing steps.

FIGS. 18(a)-(c) are cross-sectional views illustrating a conventional DRAM after various processing steps.

FIGS. 19(d)-(e) are cross-sectional views illustrating a conventional DRAM after various processing steps.

FIGS. 20(f)-(h) are cross-sectional views illustrating a conventional DRAM after various processing steps.

FIGS. 21(i)-(k) are cross-sectional views illustrating a conventional DRAM after various processing steps.

### DETAILED DESCRIPTION OF THE EMBODIMENTS

Various embodiments of the present invention will now be described in detail with reference to a number of drawings.

### Embodiment 1

The present embodiment is one example where a semiconductor device of the present invention may be applied to a dynamic random access memory (DRAM).

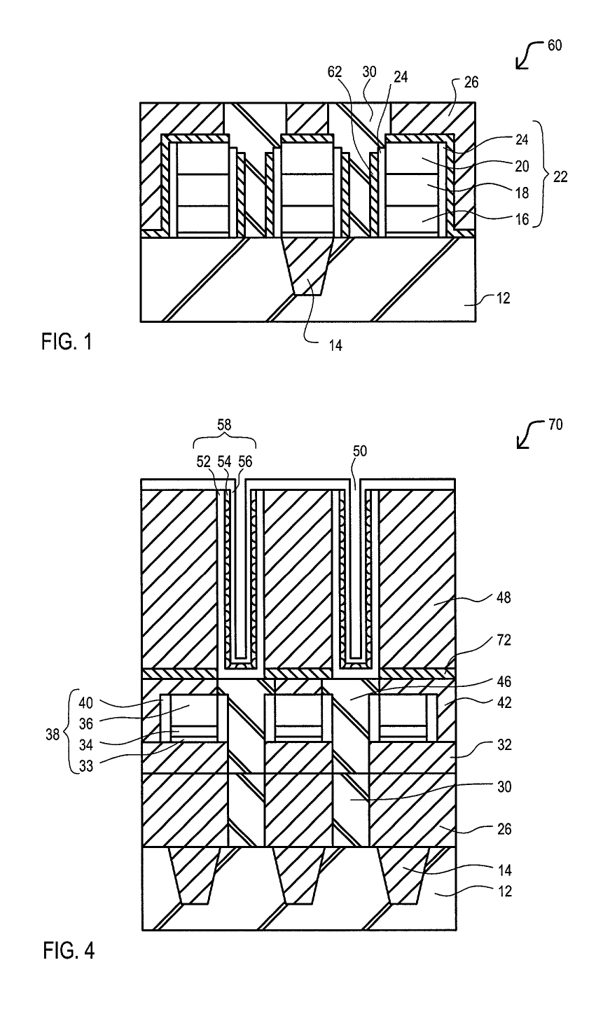

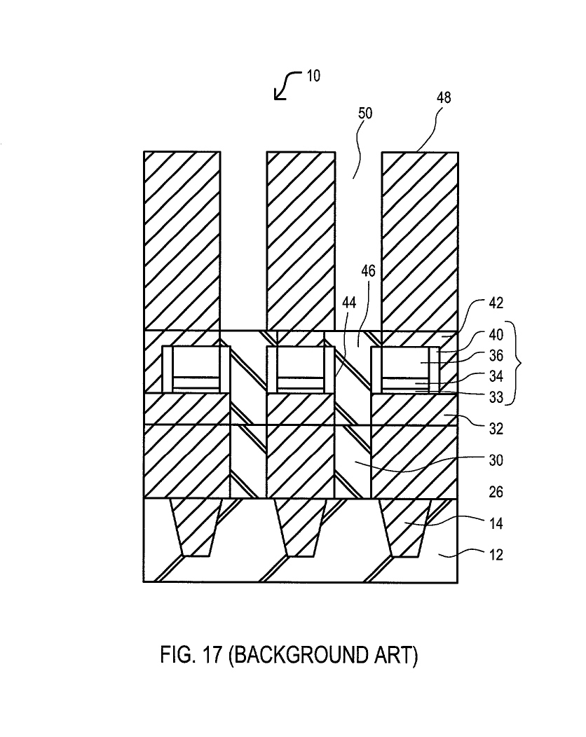

Referring now to FIG. 1, a cross-sectional view of a portion of a DRAM after various processing steps according to an embodiment is set forth and given the general reference character 60. DRAM 60 may include similar constituents as conventional DRAM 10 as illustrated in FIGS. 16 and 17, such constituents may be referred to by the same reference character and the descriptions as such may be omitted.

Semiconductor device 60 may include a Ta₂O₅ film formed from gas containing carbon as a capacitor insulating film. For example, Ta(OC₂H₅)₅ may be used to form a capacitor insulating film in a capacitor section. As illustrated in FIG. 1, an approximately 100 Å thick Si₃N₄ film 62 may be formed on silicon substrate 12 within a cell contact hole. Si₃N₄ film 62 may be used as a carbon diffusion prevention film for preventing diffusion of carbon during the formation of the capacitor insulating film (Ta₂O₅ film) of the capacitor section.

DRAM 60 may include a cell contact plug 30 that may penetrate first interlayer insulating film 26 and may be connected with a diffusion layer formed in silicon substrate 12. Si₃N₄ film 62 may be formed on silicon substrate 12 and on an upper surface and side of word line 22 while partially traversing a region formed by the cell contact hole before being filled with the cell contact plug 30. In this way, Si₃N₄ film 62 may be used as the carbon diffusion prevention film.

Otherwise, DRAM 60 may have a similar construction of the transistor section and capacitor section as the conventional DRAM 10 illustrated in FIGS. 16 and 17.

In the embodiments 1 to 3 of the semiconductor device and in the embodiments 1 to 4 of the method for manufacturing a semiconductor device a SiO₂ film may be used as the first to fourth interlayer insulating films.

### Embodiment 1 of the Method for Manufacturing the Semiconductor Device

The present embodiment is one example of the method for manufacturing a semiconductor device as applied to manufacturing DRAM 60 of embodiment 1.

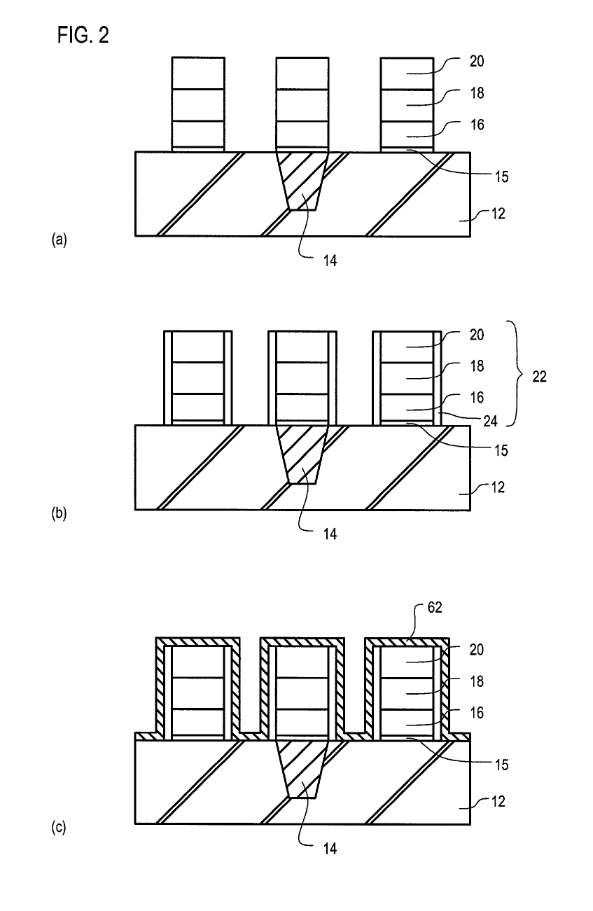

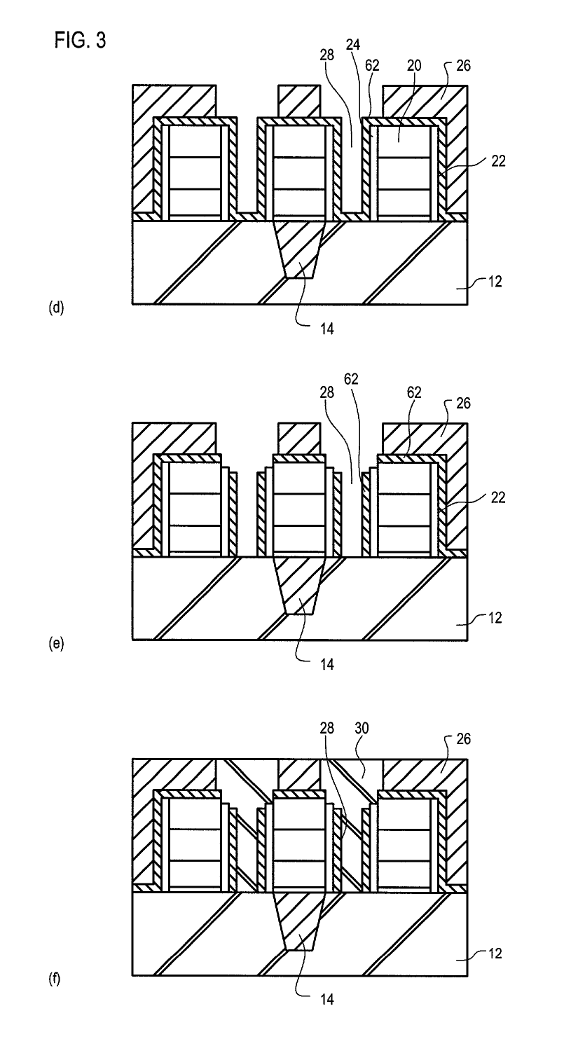

FIGS. 2(a)-(c) and FIGS. 3(d)-(f) are cross-sectional views illustrating DRAM 60 after various processing steps according to an embodiment. DRAM 60 may include similar constituents as conventional DRAM 10 as illustrated in FIGS. 16 and 17, and such constituents may be referred to by the same reference character and the descriptions as such may be omitted.

As illustrated in FIG. 2(a), shallow trench isolation (STI) 14 may be formed on silicon substrate 12 providing a device isolation region to define a transistor formation region. In the transistor formation region, a diffusion layer that includes a channel region and source/drain regions (not shown) may be formed. A wiring structure may be formed including a laminate film composed of gate oxide film 15, DOPOS film 16, WSi film 18 and silicon nitride film 20.

Next, silicon nitride film 24 may be formed on the laminate film and may be etched back to form silicon nitride film sidewall 24 on the side of the laminate film as illustrated in FIG. 2(b). Word line 22 may be thus formed and may provide a gate electrode for a transistor formed in the transistor formation region.

Referring now to FIG. 2(c), an approximately 100 Å thick blanket silicon nitride film (Si₃N₄ film) 62 may be formed on the entire surface of the substrate using a low pressure chemical vapor deposition (LP-CVD) method.

Blanket silicon nitride film (Si₃N₄ film) 62 may be formed with an LP-CVD method. Gas flow rate conditions may be used in which an approximately 100 Å thick stoichiometric composition (Si₃N₄) may be obtained at a temperature of approximately 760° C., and a pressure of approximately 0.2 Torr. A composition and flow rate of a stock gas may be approximately 75 sccm for dichlorosilane and approximately 750 sccm for ammonia. The film formation conditions may be the same in embodiments 2 to 4.

A fine quality silicon nitride film may be required for preventing carbon from diffusing. A Si₃N₄ film formed using a LP-CVD method may be more preferable than the silicon nitride film formed by a plasma CVD method such that the composition may be different from the stoichiometric composition.

Referring now to FIG. 3(d), a first interlayer insulating film 26 may be formed over the entire surface of the substrate to bury the word line 22. First interlayer insulating film 26 may then be etched with an etching method that may be selective for silicon nitride films (20 and 24) and Si₃N₄ film 62 to form a cell contact hole 28.

Referring now to FIG. 3(e), although Si₃N₄ film 62 at an upper comer or shoulder of the opening of cell contact hole 28 may also be removed, silicon nitride film 20 and side wall silicon nitride film 24 may remain so that the object and the effect of the present invention is not obstructed.

Referring now to FIG. 3(f), an electrically conductive material such as DOPOS and tungsten (W) may be deposited on the entire surface of the substrate to fill cell contact hole 28. The electrically conductive material on first interlayer insulating film 26 may be removed with an entire etching back or CMP method to form cell contact plug 30 which may be connected with a diffusion layer of silicon substrate 12.

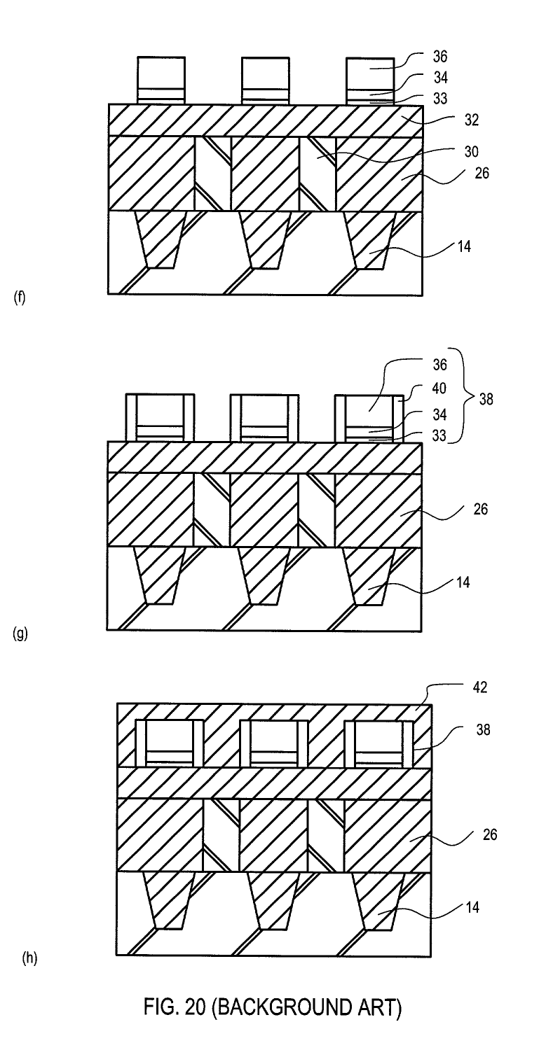

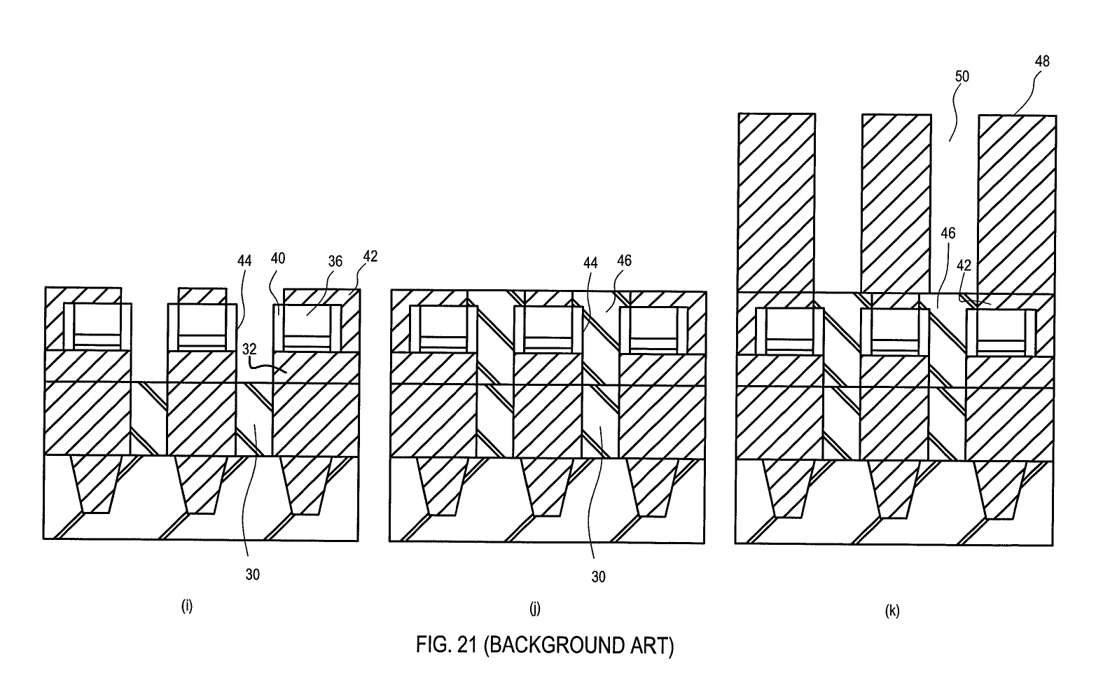

Hereinafter, respective processes that are similar to the conventional process described with reference to FIG. 20(f) to FIG. 21(k) may be executed to manufacture DRAM 60.

### Embodiment 2 of a Semiconductor Device

The present embodiment is another example where a semiconductor device of the present invention may be applied to a dynamic random access memory (DRAM).

Referring now to FIG. 4, a cross-sectional view of a portion of a DRAM after various processing steps according to an embodiment is set forth and given the general reference character 70. DRAM 70 may include similar constituents as conventional DRAM 10 as illustrated in FIGS. 16 and 17, such constituents may be referred to by the same reference character and the descriptions as such may be omitted.

Semiconductor device 70 may include a Ta₂O₅ film formed from gas containing carbon as a capacitor insulating film. For example, Ta(OC₂H₅)₅ may be used to form a capacitor insulating film in a capacitor section.

As illustrated in FIG. 4, an approximately 100 Å thick Si₃N₄ film 72 maybe formed in a region above third interlayer insulating film 42 with the exception of a bottom of a cylindrical capacitor formation section 50. Si₃N₄ film 72 may be used as a carbon diffusion prevention film for preventing diffusion of carbon during the formation of the capacitor insulating film (Ta₂O₅ film) of the capacitor section.

DRAM 70 may include a cell contact plug 30 that may penetrate first interlayer insulating film 26 and may be connected with a diffusion layer formed in silicon substrate 12. A capacitor contact plug 46 may be interposed between a lower electrode 52 of capacitor section 58 and cell contact plug 30 while penetrating third interlayer insulating film 42, and second interlayer insulating film 32 to connect lower electrode 52 to cell contact plug 30. Si₃N₄ film 72 may be formed over third layer insulating film 42 with the exception of a connection portion between lower electrode 52 and capacitor contact plug 46. In this way, Si₃N₄ film 72 may be used as the carbon diffusion prevention film.

Otherwise, DRAM 70 may have a similar construction of the transistor section and capacitor section as the conventional DRAM 10 illustrated in FIGS. 16 and 17.

As illustrated in FIG. 4, the DRAM of the present embodiment may include capacitor 58. Capacitor 58 may include a lower electrode 52, a capacitor insulating film 54, and an upper electrode (plate electrode) 56 formed in cylindrical capacitor formation section 50. Lower electrode 52 may include a DOPOS film converted to HSG (Hemi-Spherical Grain) and may be connected with capacitor contact plug 46. Capacitor insulating film 54 may be an approximately 80 Å thick Ta₂O₅ film. Upper electrode may be a TiN film.

### Embodiment 2 of the Method for Manufacturing the Semiconductor Device

The present embodiment is one example of the method for manufacturing a semiconductor device as applied to manufacturing DRAM 70 of embodiment 2.

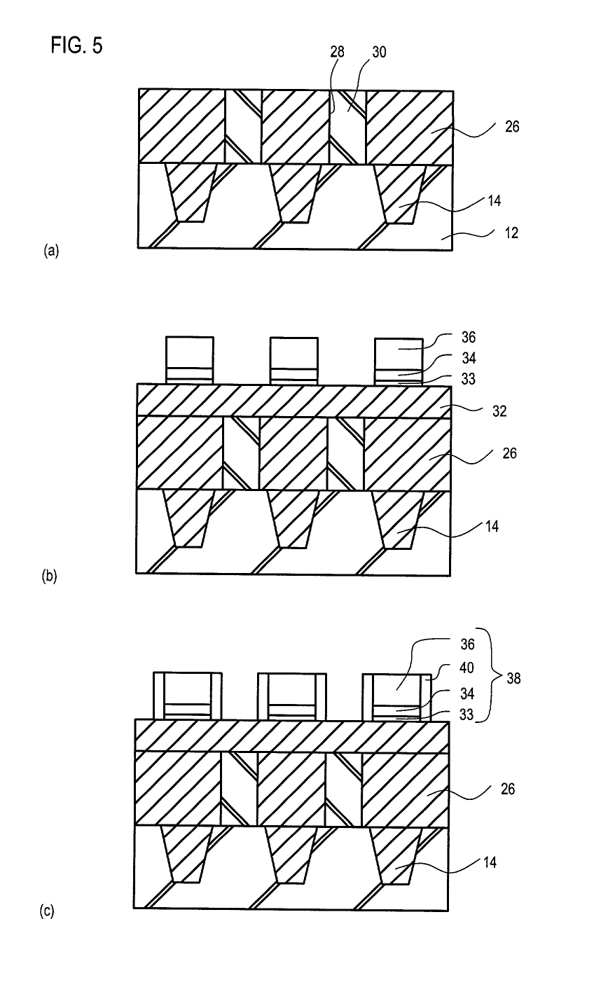

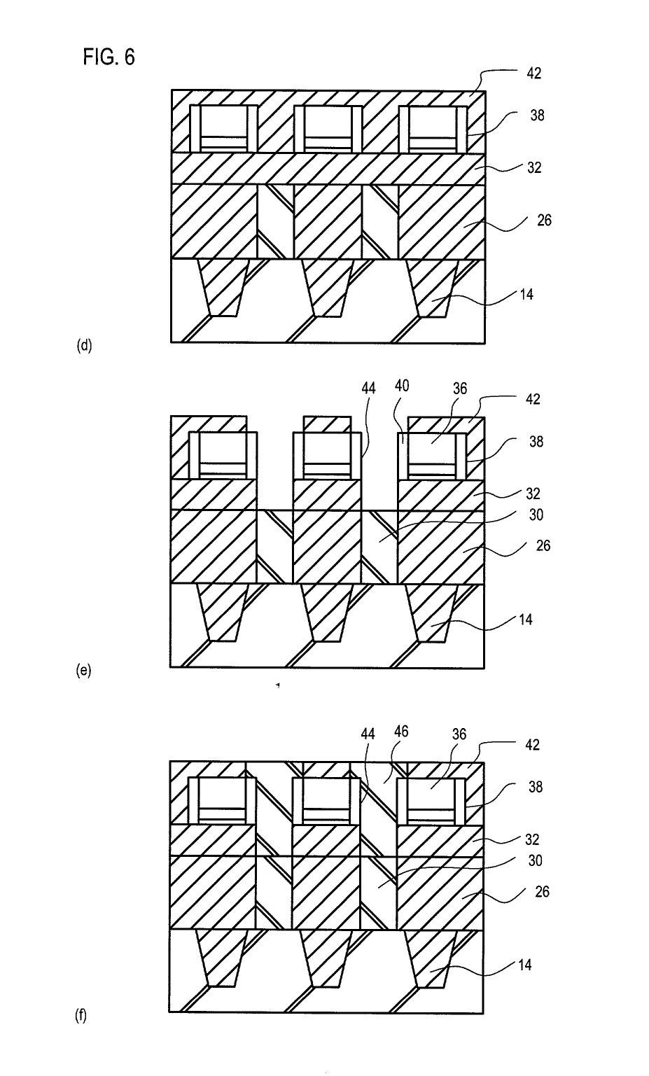

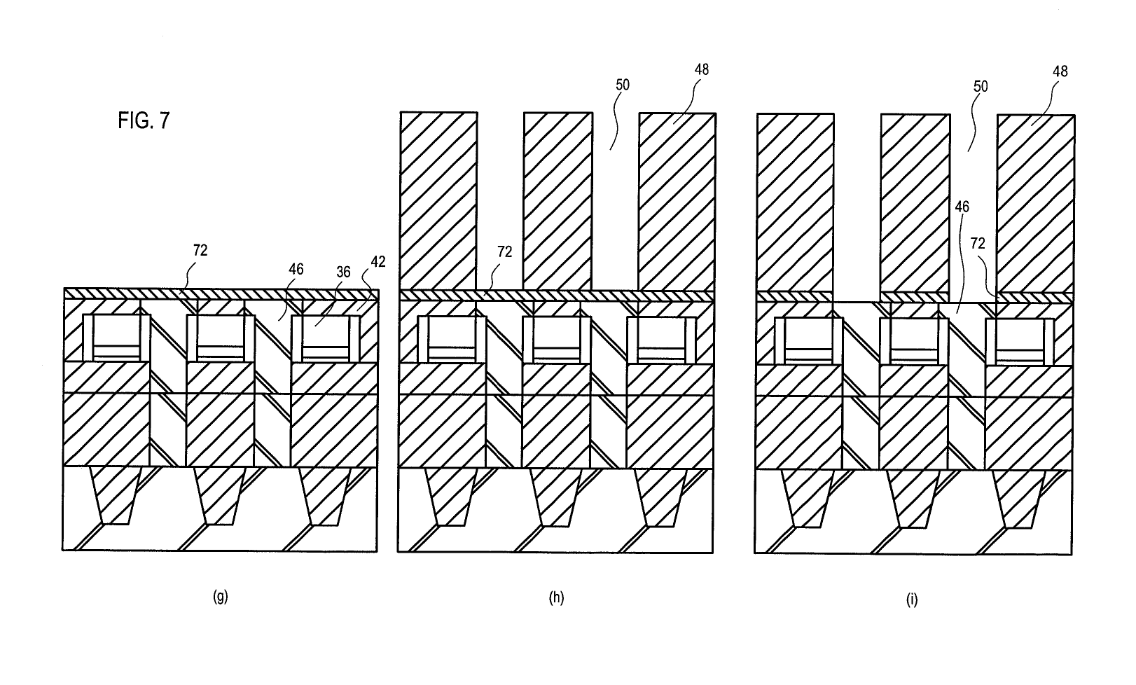

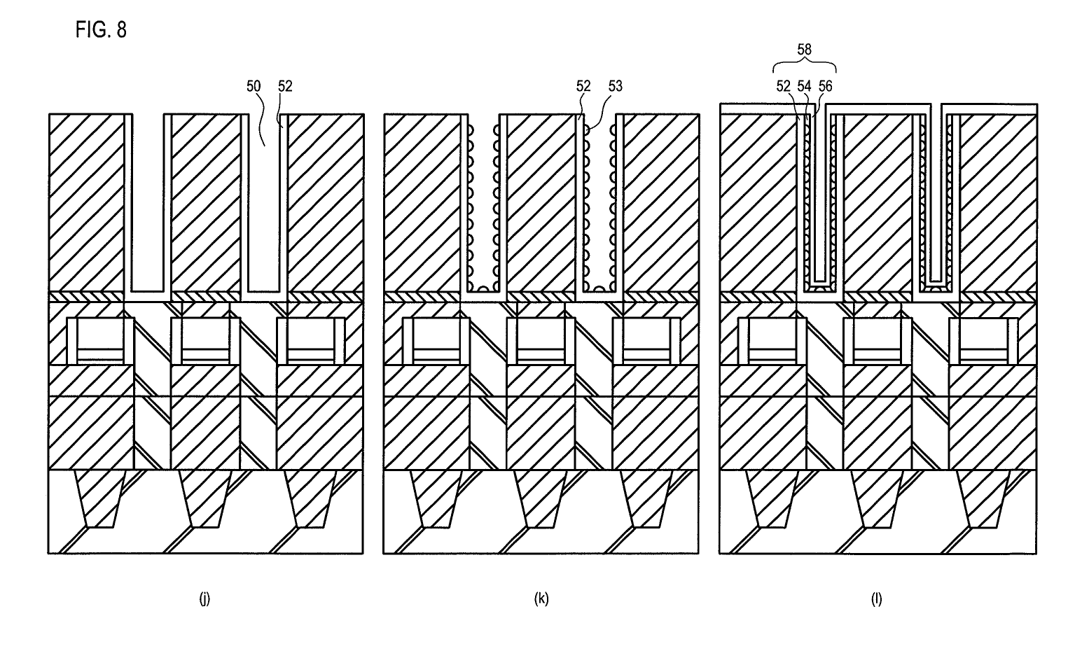

FIGS. 5(a)-(c), FIGS. 6(d)-(f), FIGS. 7(g)-(i), and FIGS. 8(j)-(l) are cross-sectional views illustrating DRAM 70 after various processing steps according to an embodiment. DRAM 70 may include similar constituents as conventional DRAM 10 as illustrated in FIGS. 16 to 21, and such constituents may be referred to by the same reference character and the descriptions as such may be omitted.

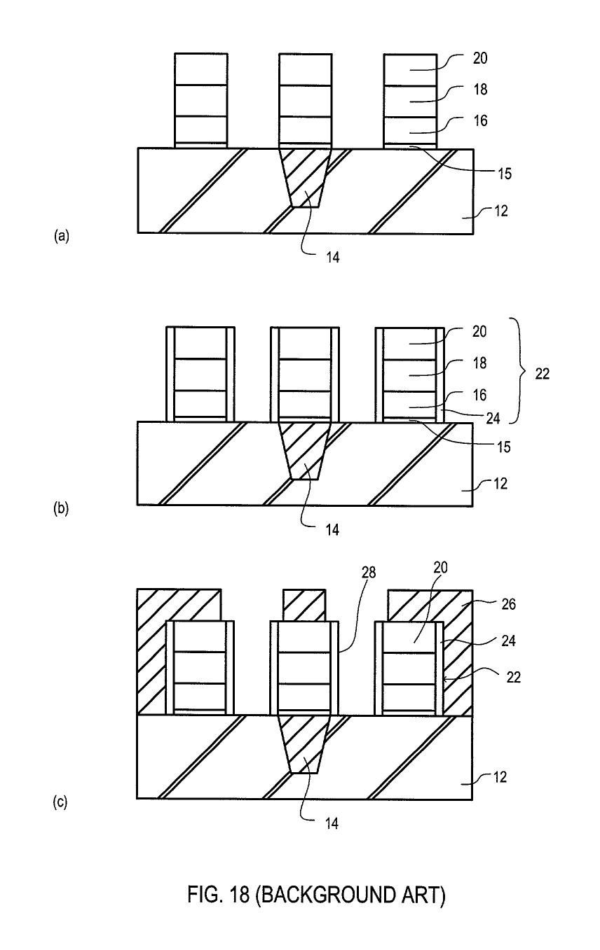

Referring once again to FIGS. 18(a) to 18(c), in a similar fashion as the conventional method, STI 14 may be formed on silicon substrate 12 providing a device isolation region to define a transistor formation region. In the transistor formation region, a diffusion layer that includes a channel region and source/drain regions (not shown) may be formed. A wiring structure may be formed including a laminate film composed of gate oxide film 15, DOPOS film 16, WSi film 18 and silicon nitride film 20 to be used as word line 22. Word line 22 may also include a silicon nitride film side wall 24.

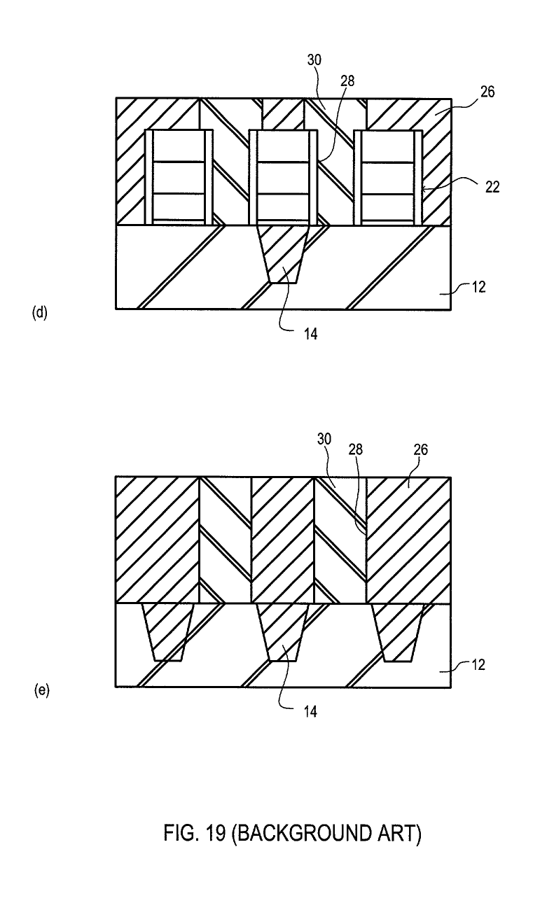

Referring to FIGS. 19(d) and 19(e), first interlayer insulating film 26 may be formed on the entire surface of the substrate and may bury word line 22. Then first interlayer insulating film 26 may be etched to form cell contact hole 28.

Electrically conductive material such as DOPOS and tungsten (W) may be deposited on the entire surface of the substrate filling cell contact hole 28 and covering first interlayer insulating film 26. An entire surface etching back or CMP may be performed to form cell contact plug 30 and expose first interlayer insulating film 26.

In this way, an intermediate structure of a DRAM having a structure illustrated by the cross-section view of FIG. 5(a) may be formed.

Referring now to FIG. 5(b), second interlayer insulating film 32 may be formed on first interlayer insulating film 26 and cell contact plug 30. A wiring including a laminate film of WN film 33, W film 34, and silicon nitride film 36 may be formed on second interlayer insulating film 32.

Referring now to FIG. 5(c), a silicon nitride film may be formed on the wiring and etched back to form a silicon nitride film sidewall 40 on the side of the laminate film. In this way, bit line 38 maybe formed.

Referring now to FIG. 6(d), third interlayer insulating film 42 may be formed on the entire surface of the substrate to bury bit line 38.

Referring now to FIG. 6(e), third interlayer insulating film 42 and second interlayer insulating film 32 may be etched by an etching method selective for silicon nitride films (36 and 40) to form contact hole 44. In this way, cell contact plug 30 may be exposed for the formation of a capacitor contact.

Referring now to FIG. 6(f), an electrically conductive material film such as a DOPOS film and a tungsten film may be formed on the substrate to fill contact hole 44 and cover third interlayer insulating film 42. Then the electrically conductive film may be removed by an entire surface etching back or CMP method to form capacitor contact plug 46. Capacitor contact plug 46 may be connected with cell contact plug 30 and may be made of the electrically conductive material.

Referring now to FIG. 7(g), an approximately 100 Å thick blanket silicon nitride film (Si₃N₄ film) 72 may then be formed on third interlayer insulating film 42 and capacitor contact plug 46 with a LP-CVD method.

Referring now to FIG. 7(h), fourth interlayer insulating film 48 may then be formed on Si₃N₄ film 72. Fourth interlayer insulating film 48 may then be patterned and etched to form deeply recessed cylindrical capacitor formation section 50 in which Si₃N₄ film 72 may be exposed. Cylindrical capacitor formation section 50 may be used for the formation of a cylindrical capacitor.

Referring now to FIG. 7(i), Si₃N₄ film 72 at the bottom of cylindrical capacitor formation section 50 may be selectively etched and removed to expose capacitor contact plug 45.

Referring now to FIG. 8(j), DOPOS film 52 may be formed on the bottom and side of cylindrical capacitor formation section 50.

Referring now to FIG. 8(k), the surface of DOPOS film 52 may be changed to form an electrode having HSG (Hemi-Spherical Grain) 53.

Referring now to FIG. 8(l), a Ta₂O₅ film 54 may be formed on DOPOS film 52 including HSG and may provide a capacitor insulating film. A TiN film 56 may then be formed on Ta₂O₅ film 54 with a CVD method and may be patterned into an upper electrode (plate electrode) 56 to make capacitor 58.

Upon formation of the Ta₂O₅ film 54, Ta(OC₂H₅)₅ may be used as a stock gas to form approximately 80 Å thick Ta₂O₅ at a temperature of approximately 500° C. and a pressure of about 4 Torr with a CVD method. Then Ta₂O₅ film may be oxidized at a temperature of approximately 500° C. with the use of UV-O₃ (Ultraviolet Ozone) and may be crystallized at a temperature of about 750° C. with the use of O₂ dry oxidization to form stoichiometric Ta₂O₅ film.

### Embodiment 3 of the Method for Manufacturing a Semiconductor Device

The present embodiment is one example of the method for manufacturing a semiconductor device as applied to manufacturing DRAM 70 of embodiment 2.

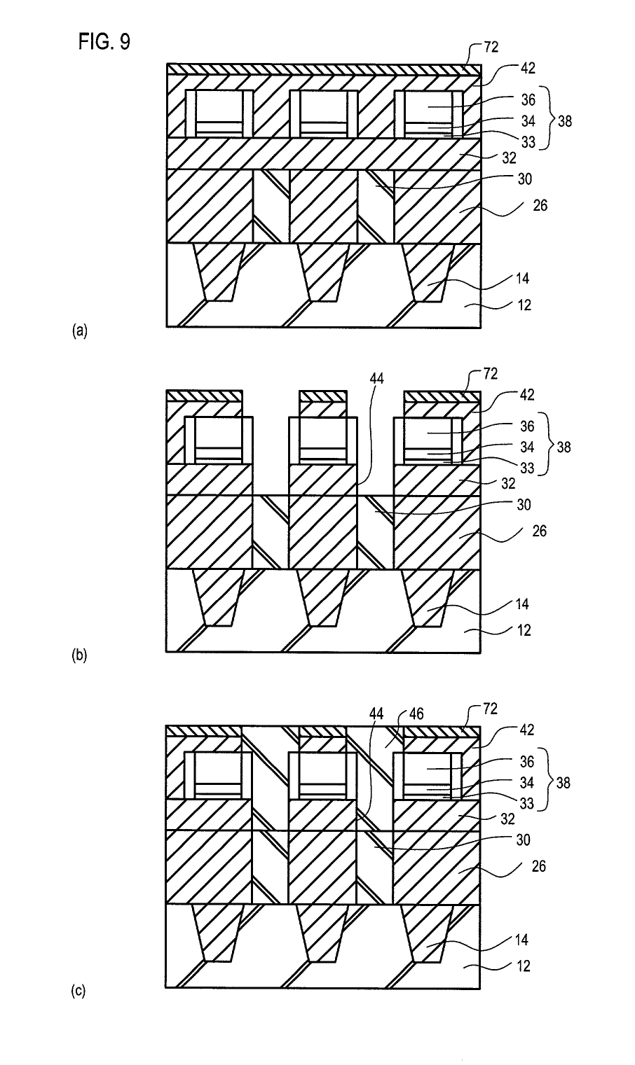

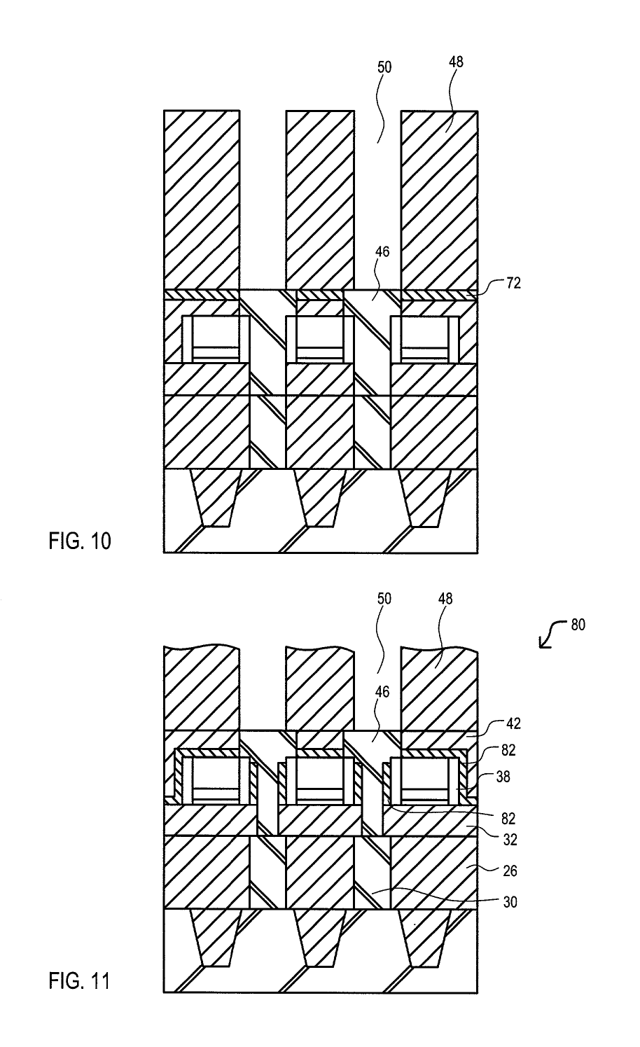

FIGS. 9(a)-(c) and FIG. 10 are cross-sectional views illustrating DRAM 70 after various processing steps according to an embodiment. DRAM 70 may include similar constituents as conventional DRAM 10 as illustrated in FIGS. 16 and 17, and such constituents may be referred to by the same reference character and the descriptions as such may be omitted.

In the present embodiment, STI 14 may be formed on silicon substrate 12 providing a device isolation region to define a transistor formation region. In the transistor formation region, a diffusion layer that includes a channel region and source/drain regions (not shown) may be formed. A wiring structure may be formed including a laminate film composed of gate oxide film 15, DOPOS film 16, TiSi film 18 and silicon nitride film 20 to be used as word line 22. Word line 22 may also include a silicon nitride film side wall 24.

Next, first interlayer insulating film 26 may be formed on the entire surface of the substrate and may bury word line 22. Then first interlayer insulating film 26 may be etched to form cell contact hole 28.

Electrically conductive material such as DOPOS and tungsten (W) may be deposited on the entire surface of the substrate filling cell contact hole 28 and covering first interlayer insulating film 26. An entire surface etching back or CMP may be performed to form cell contact plug 30 and expose first interlayer insulating film 26.

Further, in a similar fashion as the method of embodiment 2, a second interlayer insulating film 32 may be formed on first interlayer insulating film 26 and cell contact plug 30. A wiring including a laminate film of WN film 33, W film 34, and silicon nitride film 36 may be formed on second interlayer insulating film 32. A silicon nitride film may then be formed on the wiring and etched back to form a silicon nitride film sidewall 40 on the side of the laminate film. In this way, bit line 38 may be formed.

Finally, third interlayer insulating film 42 may be formed on the entire surface of the substrate to bury bit line 38.

In this way, an intermediate structure of a DRAM having a structure illustrated by the cross-section view of FIG. 6(d), illustrated in embodiment 2, may be formed.

Referring now to FIG. 9(a), the method of the present embodiment may be different than the method of embodiment 2. An approximately 100 Å thick blanket silicon nitride film (Si₃N₄ film) 72 may be formed on third layer insulating film 42 with a LP-CVD method.

Successively, a mask (not shown) including a resist film having a capacitor contact hole pattern may be formed on blanket silicon nitride film 72. Blanket silicon nitride film 72 may then be etched using the mask.

Referring now to FIG. 9(b), after blanket silicon nitride film 72 is etched, third interlayer insulating film 42 and second interlayer insulating film 32 may be etched with an etching method selective for silicon nitride films (36 and 40) and Si₃N₄ film 72 to form a contact hole 44. Contact hole 44 may expose cell contact plug 30 and may be used for the formation of a capacitor contact.

Referring now to FIG. 9(c), an electrically conductive material film such as a DOPOS film and a tungsten film may be formed on the silicon substrate to fill contact hole 44 and cover Si₃N₄ film 72. An entire surface etching back or CMP may be performed to form capacitor contact plug 46. Capacitor contact plug 46 may be connected with cell contact plug 30 and may be made of the electrically conductive material.

Referring now to FIG. 10, fourth interlayer insulating film 48 may be formed on Si₃N₄ film 72 and capacitor contact plug 46 and may be patterned to form deeply recessed cylindrical capacitor formation section 50 in which capacitor contact plug 46 may be exposed. Cylindrical capacitor formation section 50 may be used for the formation of a cylindrical capacitor.

Hereafter, a lower electrode, a capacitor insulating film, and an upper electrode may be formed in a similar manner as in the method of embodiment 2.

### Embodiment 3 of a Semiconductor Device

The present embodiment is another example where a semiconductor device of the present invention may be applied to a dynamic random access memory (DRAM).

Referring now to FIG. 11, a cross-sectional view of a portion of a DRAM after various processing steps according to an embodiment is set forth and given the general reference character 80. DRAM 80 may include similar constituents as conventional DRAM 10 as illustrated in FIGS. 16 and 17, such constituents may be referred to by the same reference character and the descriptions as such may be omitted.

Semiconductor device 80 may include a Ta₂O₅ film formed from gas containing carbon as a capacitor insulating film. For example, Ta(OC₂H₅)₅ may be used to form a capacitor insulting film in a capacitor section.

As illustrated in FIG. 11, an approximately 100 Å thick Si₃N₄ film 82 may be formed in a region on second interlayer insulating film 32 with the exception of a formation region of a capacitor contact plug 46. Si₃N₄ film 82 may be used as a carbon diffusion prevention film for preventing diffusion of carbon during the formation of the capacitor insulating film (Ta₂O₅ film) of the capacitor section.

DRAM 80 may include a cell contact plug 30 that may penetrate first interlayer insulating film 26 and may be connected with a diffusion layer formed in silicon substrate 12. A capacitor contact plug 46 may be interposed between a lower electrode of the capacitor section 50 and cell contact plug 30 while penetrating third interlayer insulating film 42, and second interlayer insulating film 32 to connect the lower electrode to cell contact plug 30. Si₃N₄ film 82 may be formed on second layer insulating film 32 with the exception of a formation region of a capacitor contact plug 46. In this way, Si₃N₄ film 82 may be used as the carbon diffusion prevention film.

Otherwise, DRAM 80 may have a similar construction of the transistor section and capacitor section as the conventional DRAM 10 illustrated in FIGS. 16 and 17.

Although not illustrated, DRAM 80 of the present embodiment may include a capacitor 58 similar to embodiment 2. As illustrated in embodiment 2, capacitor 58 may include a lower electrode 52, a capacitor insulating film 54, and an upper electrode (plate electrode) 56 formed in cylindrical capacitor formation section 50. Lower electrode 52 may include a DOPOS film converted to HSG (Hemi-Spherical Grain) and may be connected with capacitor plug 46. Capacitor insulating film 54 may be an approximately 80 Å thick Ta₂O₅ film. Upper electrode may be a TiN film.

### Embodiment 4 of the Method for Manufacturing the Semiconductor Device

The present embodiment is one example of the method for manufacturing a semiconductor device as applied to manufacturing DRAM 80 of embodiment 3.

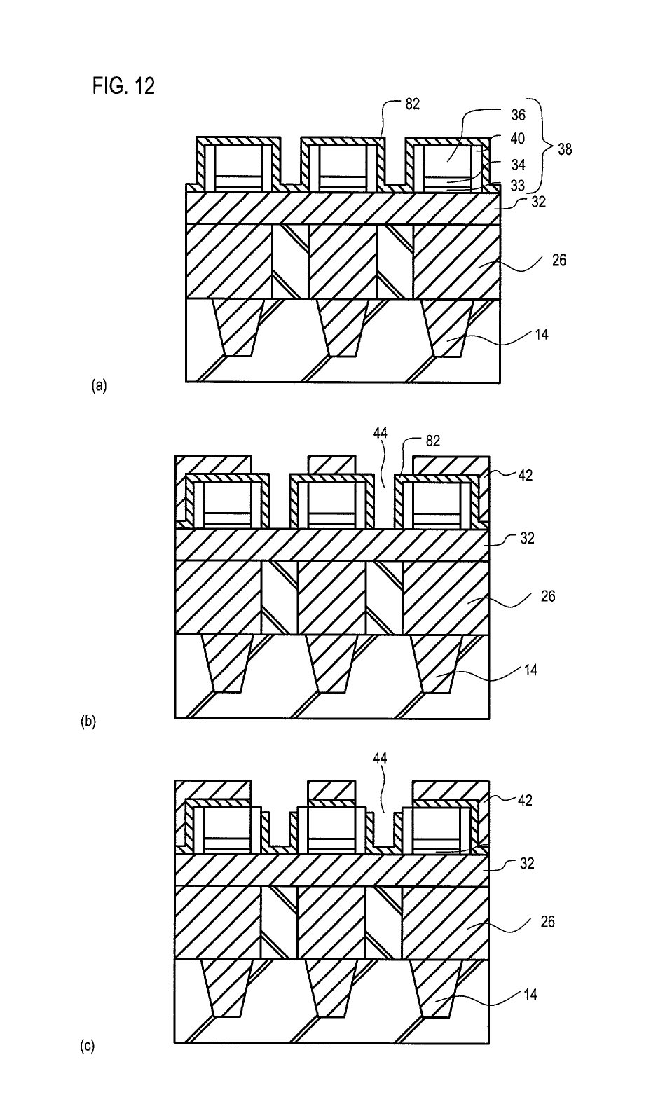

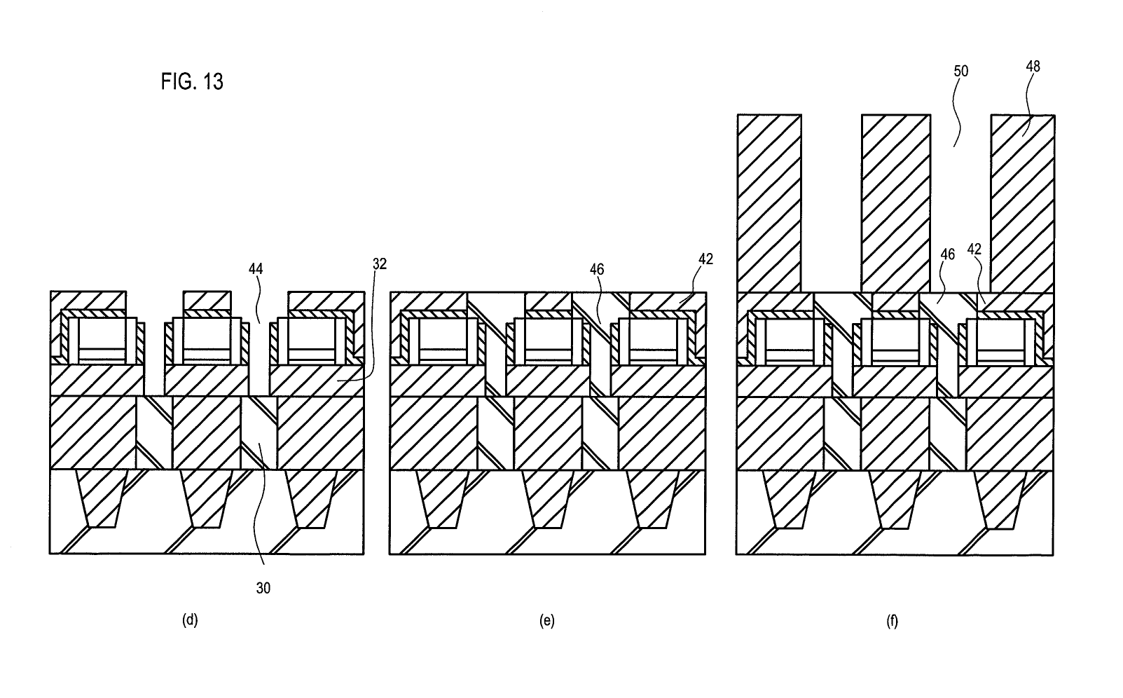

FIGS. 12(a)-(c) and FIG. 13(d)-(f) are cross-sectional views illustrating DRAM 80 after various processing steps according to an embodiment. DRAM 80 may include similar constituents as conventional DRAM as illustrated in FIGS. 18 to 21, and such constituents may be referred to by the same reference character and the descriptions as such may be omitted.

In a similar fashion as the embodiment 2, STI 14 may be formed on silicon substrate 12 providing a device isolation region to define a transistor formation region. In the transistor formation region, a diffusion layer that includes a channel region and source/drain regions (not shown) may be formed. A wiring structure may be formed including a laminate film composed of gate oxide film 15, DOPOS film 16, WSi film 18 and silicon nitride film 20 to be used as word line 22. Word line 22 may also include a silicon nitride film side wall 24.

First interlayer insulating film 26 may be formed on the entire surface of the substrate and may bury word line 22. Then first interlayer insulating film 26 may be etched to form cell contact hole 28.

Electrically conductive material such as DOPOS and tungsten (W) may be deposited on the entire surface of the substrate filling cell contact hole 28 and covering first interlayer insulating film 26. An entire surface etching back or CMP may be performed to form cell contact plug 30 and expose first interlayer insulating film 26, forming a structure as illustrated by the cross-section view of FIG. 5(a).

Second interlayer insulating film 32 may be formed on first interlayer insulating film 26 and cell contact plug 30. A wiring including a laminate film of WN film 33, W film 34, and silicon nitride film 36 may be formed on second interlayer insulating film 32, forming a structure as illustrated by the cross-section view of FIG. 5(b).

Next, a silicon nitride film may be formed on the wiring and etched back to form a silicon nitride film sidewall 40 on the side of the laminate film. In this way, bit line 38 may be formed.

In this way, an intermediate structure of a DRAM having a structure illustrated by the cross-section view of FIG. 5(c) may be formed.

Referring now to FIG. 12(a), in the present embodiment an approximately 100 Å thick blanket silicon nitride film (Si₃N₄ film) 82 may then be formed on the entire silicon substrate with a LP-CVD method.

Referring now to FIG. 12(b), a third interlayer insulating film 42 may be formed on the entire surface of the substrate to bury bit line 38 and Si₃N₄ film 82.

The third interlayer insulating film 42 may be etched by an etching method selective for silicon nitride films (82) to form contact hole 44. In this way, Si₃N₄ film 82 at the bottom of contact hole 44 may be exposed.

Referring now to FIG. 12(c), Si₃N₄ film 82 exposed at the bottom of contact hole may be selectively etched to expose second interlayer insulating film 32.

Referring now to FIG. 13(d), second interlayer insulating film 32 exposed at the bottom of the contact hole 44 may be etched to expose cell contact plug 30.

Referring now to FIG. 13(e), an electrically conductive material film such as a DOPOS film and a tungsten film may be formed on the substrate to fill contact hole 44 and cover third interlayer insulating film 42. Then the electrically conductive film may be removed by an entire surface etching back or CMP method to form capacitor contact plug 46. Capacitor contact plug 46 may be connected with cell contact plug 30 and may be made of the electrically conductive material.

Referring now to FIG. 13(f), fourth interlayer insulating film 48 may then be formed on third interlayer insulating film 42 and capacitor contact plug 46. Fourth interlayer insulating film 48 may then be patterned and etched to form deeply recessed cylindrical capacitor formation section 50 in which capacitor contact plug 46 may be exposed. Cylindrical capacitor formation section 50 may be used for the formation of a cylindrical capacitor.

Thereafter, a lower electrode, a capacitor insulating film and an upper electrode may be formed in a similar fashion as the method of embodiment 2.

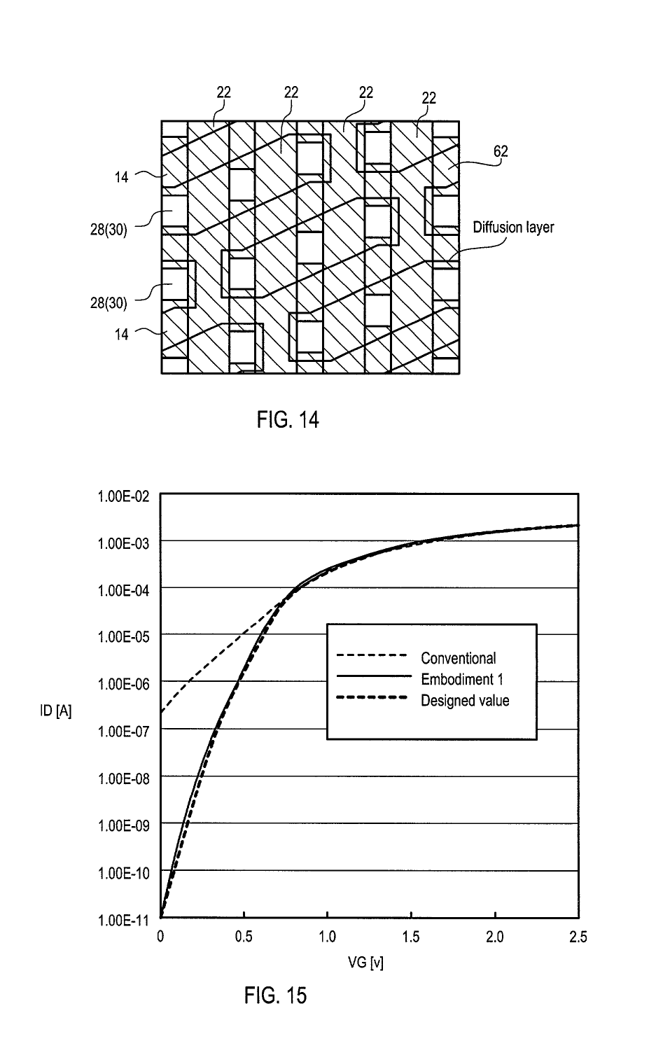

Referring now to FIG. 14, a top plan view of the structure of DRAM 60 is set forth. In DRAM 60 of embodiment 1, Si₃N₄ film 62 (indicated by hatching) may be formed as a carbon diffusion prevention film on all regions except the bottom of contact holes 28 where cell contact plug 30 may be formed, i.e., not only on word lines 22, but also on the diffusion layer, the STI 14, and between word lines 22, as illustrated in FIG. 14.

In contrast, in the conventional DRAM 10, silicon nitride film 24 is formed only on the word line 22.

Therefore, DRAM 60 of embodiment 1 may have a very high covering rate by the silicon nitride film of silicon substrate 12 compared with conventional DRAM 10 and the quality of the silicon nitride film may be improved so that the diffusion of carbon into the silicon substrate may be prevented when the Ta₂O₅ film is formed as the capacitor insulation film of the capacitor section.

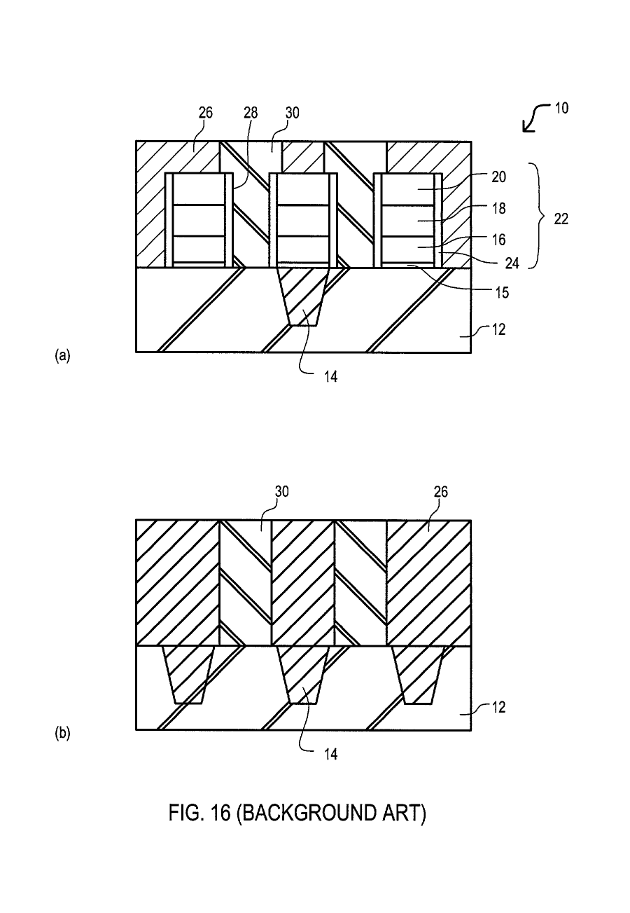

Referring now to FIG. 15, a graph illustrating the current-voltage characteristics of a transistor such as a MOSFET formed on a DRAM 60 of embodiment 1 is set forth.

In FIG. 15, the current-voltage characteristics of the transistor formed with the method of embodiment 1 is illustrated as a solid line. Also, an ideal designed current-voltage characteristic is illustrated with a thicker dashed line. It is noted that the current-voltage characteristics of the transistor formed with the method of embodiment 1 closely matches the ideal designed value. Also, the threshold voltage of the transistor formed with the method of embodiment 1 closely matches the ideal designed low value.

Furthermore, when experimental products having respective constructions of DRAM 70 of embodiment 2 and DRAM 80 of embodiment 3 are manufactured, current-voltage characteristics of the transistors have a similar result as with DRAM 60 of embodiment 1.

In accordance with the present invention, in a semiconductor device that includes a transistor structure on a semiconductor substrate so that the transistor structure may include an insulating film formed from gas containing carbon (a Ta₂O₅ film formed from Ta(OC₂H₅)₅), a silicon nitride film may be formed between the Ta₂O₅ film and the silicon substrate as a carbon diffusion prevention film. In this way, carbon diffusion to a silicon substrate may be effectively prevented when the Ta₂O₅ film is formed.

In this way, a characteristic of a transistor on the semiconductor device may be prevented from diverging from a predetermined value so that the characteristic may more closely match a desired designed value.

The present inventive method may realize a preferable manufacturing method of a semiconductor device associated with the present invention.

It is understood that the embodiments described above are exemplary and the present invention should not be limited to those embodiments. Specific structures should not be limited to the described embodiments.

Thus, while the various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A semiconductor device on a silicon substrate, having a device structure including an insulating film formed from gas containing carbon, comprising:
a silicon nitride film formed between the insulating film and the silicon substrate for preventing carbon from diffusing to the silicon substrate.

2. The semiconductor device according to claim 1, wherein:
the insulating film includes tantalum oxide (Ta₂O₅).

3. The semiconductor device of claim 2, wherein:
the semiconductor device is a dynamic random access memory having a memory cell capacitor film including the tantalum oxide.

4. The semiconductor device of claim 3, wherein:
the semiconductor device includes a contact which penetrates an interlayer insulating film and is electrically connected with a diffusion layer in the silicon substrate; and
the silicon nitride film is formed on the silicon substrate as a carbon diffusion preventing film while traversing a region except a portion for providing the electrical connection between the contact and the diffusion layer.

5. The semiconductor device of claim 3, wherein:
the semiconductor device includes a contact that penetrates a first interlayer insulating film and is electrically connected with a diffusion layer formed in the silicon substrate and a capacitor contact that is interposed between a lower electrode of the memory cell capacitor and the contact while penetrating a second interlayer insulating film and a third interlayer insulating film; and
the silicon nitride film is formed on the third interlayer insulating film while traversing a region except a connection portion between the lower electrode and the capacitor contact.

6. The semiconductor device of claim 3, wherein:
the semiconductor device includes a contact that is electrically connected with the diffusion layer formed in the silicon substrate while penetrating the first interlayer insulating film;
the contact is electrically connected to a capacitor contact that is interposed between a lower electrode of the memory cell capacitor and the contact while penetrating a second interlayer insulating film and a third interlayer insulating film for providing an electrical connection between the lower electrode and the contact; and
the silicon nitride film is formed between the second and third interlayer insulating films.

7. A method for manufacturing a semiconductor device on a silicon substrate, having a device structure including an insulating film formed from gas containing carbon, comprising the step of:
forming a silicon nitride film between the insulating film and the silicon substrate for preventing carbon from diffusing to the silicon substrate.

8. The method for manufacturing a semiconductor device of claim 7, further including the steps of:
forming a word line on a silicon substrate;
forming the silicon nitride film over the entire surface of the substrate including the word line;
forming a first interlayer insulating film on the silicon nitride film;
etching the first interlayer insulating film to form a cell contact hole with an etching method selective for the silicon nitride film to expose the silicon nitride film at a bottom of the cell contact hole;
selectively etching the silicon nitride film exposed at the bottom of the cell contact hole to expose the silicon substrate; and
forming a cell contact plug in the cell contact hole.

9. The method for manufacturing a semiconductor device of claim 8, further including the steps of:
forming a first capacitor electrode electrically connected to the cell contact plug;
forming the insulating film; and
forming a second capacitor electrode on the insulating film.

10. The method for manufacturing a semiconductor device of claim 9, wherein:
the insulating film includes tantalum oxide (Ta₂O₅).

11. The method for manufacturing a semiconductor device of claim 7, further including the steps of:
forming a word line on a silicon substrate;
forming a first interlayer insulating film on the silicon substrate including the word line;
forming a cell contact plug through the first interlayer insulating film to provide an electrical connection with a diffusion layer in the silicon substrate;
forming a second interlayer insulating film on the first interlayer insulating film;
forming a bit line on the second interlayer insulating film;
forming a third interlayer insulating film on the second interlayer insulating film including the bit line;
forming a capacitor contact plug through the second and third interlayer insulating films to provide an electrical connection to the cell contact plug; and
forming the silicon nitride film on the third interlayer insulating film and capacitor contact plug.

12. The method for manufacturing a semiconductor device of claim 11, further including the steps of:
forming a fourth interlayer insulating film on the silicon nitride film;
forming a capacitor formation section in the fourth interlayer insulating film to expose the silicon nitride film; and
etching the exposed silicon nitride film to expose the capacitor contact plug.

13. The method for manufacturing a semiconductor device of claim 12, further including the step of
forming a capacitor including the insulating film in the capacitor formation section.

14. The method for manufacturing a semiconductor device of claim 7, further including the steps of:
forming a word line on a silicon substrate;
forming a first interlayer insulating film on the silicon substrate including the word line;
forming a cell contact plug through the first interlayer insulating film to provide an electrical connection with a diffusion layer in the silicon substrate;
forming a second interlayer insulating film on the first interlayer insulating film;
forming a bit line on the second interlayer insulating film;
forming a third interlayer insulating film on the second interlayer insulating film including the bit line;
forming the silicon nitride film on the third interlayer insulating film; and
forming a capacitor contact plug through the second and third interlayer insulating films and the silicon nitride film to provide an electrical connection to the cell contact plug.

15. The method for manufacturing a semiconductor device of claim 14, further including the step of:
forming a capacitor including the insulating film and having a capacitor electrode electrically connected to the capacitor contact plug.

16. The method for manufacturing a semiconductor device of claim 7, further including the steps of:
forming a word line on a silicon substrate;
forming a first interlayer insulating film o n t he silicon substrate including the word line;
forming a cell contact plug through the first interlayer insulating film to provide an electrical connection with a diffusion layer in the silicon substrate;
forming a second interlayer insulating film on the first interlayer insulating film;
forming a bit line on the second interlayer insulating film;
forming the silicon nitride film on the second interlayer insulating film including the bit line;
forming a third interlayer insulating film on the silicon nitride film;
etching the third interlayer insulating film to form a contact hole and expose the silicon nitride film at a bottom of the contact hole;
etching the silicon nitride film at the bottom of the contact hole to expose the second interlayer insulating film;
etching the exposed second interlayer insulating film at the bottom of the contact hole to provide a capacitor contact hole including the contact hole; and
forming a capacitor contact plug through the second and third interlayer insulating films to provide an electrical connection to the cell contact plug.

17. The method for manufacturing a semiconductor device of claim 16, further including the step of:
forming a capacitor including the insulating film and having a capacitor electrode electrically connected to the capacitor contact plug.

18. A method for manufacturing a semiconductor device on a silicon substrate, having a memory cell including a capacitor insulating film formed from gas containing carbon, comprising the step of:
forming a silicon nitride film between the capacitor insulating film and the silicon substrate for preventing carbon from diffusing to the silicon substrate.

19. The method of manufacturing the semiconductor device of claim 18, wherein:
the capacitor insulating film includes tantalum oxide (Ta₂O₅).

20. The method of manufacturing the semiconductor device of claim 19, wherein:
the capacitor includes an electrode having a hemi-spherical grain structure.
